(19) United States
(12) Patent Application Publication
(10) Pub. No.: US 2010/0068896 A1
(43) Pub. Date: Mar. 18, 2010

(54) METHOD OF PROCESSING SUBSTRATE

(75) Inventors: Takuya SUGAWARA, Nirasaki City (JP); Koji YAMASHITA, Billerica, MA (US)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/560,766

(22) Filed: Sep. 16, 2009

(30) Foreign Application Priority Data
Sep. 17, 2008 (JP) 2008-237567

(51) Int. Cl. H01L 21/31

(52) U.S. Cl. 438/783; 257/E21.24

(57) ABSTRACT

A method of processing a substrate to form a thin film into which an impurity is introduced, the method including forming a thin film on the substrate; and introducing the impurity to the thin film by irradiating a gas cluster ion beam, which is generated by ionizing and accelerating a gas cluster of the impurity, onto the thin film.

### CROSS-REFERENCE TO RELATED PATENT APPLICATIONS

This application claims the benefit of Japanese Patent Application No. 2008-237567, filed on Sep. 17, 2008, in the Japan Patent Office, the disclosure of which is incorporated herein in its entirety by reference.

### BACKGROUND OF THE INVENTION

1. Field of the Invention

The present invention relates to a method of processing a substrate, and more particularly, to a method of processing a substrate, the method suitable for introducing a small quantity of an impurity into a thin film formed on the substrate.

2. Description of the Related Art

Conventionally, as a method of introducing a small quantity of an impurity into an insulating film formed on a substrate, a method including forming different insulating films and performing thermal annealing thereon to form a laminated film has been known in the field of semiconductor device fabrication. In other words, according to the method above, in order to form a ZrSiO film having a thickness of 10 nm and including a ZrO₂ film with a SiO₂ content of about 10%, a SiO₂ film with a thickness of 1 nm and a ZrO₂ film with a thickness of 9 nm are stacked, and thermal annealing is performed thereon to obtain a ZrSiO film with a SiO₂ content of about 10%. The thicknesses of each of the films may be controlled by adjusting film forming conditions such as gas, time, temperature, pressure, etc.

However, it is difficult to apply the method for forming an extremely thin film having a thickness of several nanometers or to control content of impurities as low as several percents. For example, according to the method above, a SiO₂ film having a thickness of 0.5 nm is necessary to obtain a ZrO₂ film with a thickness of 4.5 nm and a SiO₂ content of 10%. In this regard, a SiO₂ film having a thickness of 0.1 nm is necessary to obtain a ZrO₂ film with a thickness of 9.9 nm and a SiO₂ content of 1%.

However, it is difficult to form a SiO₂ film having such a small thickness. For example, when a SiO₂ film is formed by using atomic layer deposition (ALD), the thickness of a film formed in one cycle is about 0.8 nm, which is greater than the thicknesses (0.5 nm and 0.1 nm) of the SiO₂ films described above.

As described above, in a laminated film formed using a conventional method, it is difficult to control a content of an impurity introduced thereto when the thickness of an insulating film is as low as several nanometers or when required content of the impurity is as low as several percents.

A more common example will be described below. FIGS. 4(a) and 4(b) are diagrams for describing a conventional method of forming an extremely thin film containing an impurity. In FIG. 4, Ma and Mb indicate optional metal elements, and MaOx and MbOy indicate metal oxides. A and B respectively indicate thicknesses of the MaOx and MbOy. As illustrated in FIG. 4(a), MaOx and MbOy thin films are stacked and thermally annealed. Thus, referring to FIG. 4(b), a MaMbOz film, in which a MbOy is introduced into a MaOx film and which has a thickness of 2(A+B), is formed. The MbOy constitutes an impurity. Such a multi-layer film formed by using the stacked films is referred to as a laminated film.

The conventional method described above may be suitable for formation of various films containing impurities as long as the thicknesses of the MaOx film and MbOy film can be controlled. Furthermore, as illustrated in FIGS. 5(a) and 5(b), the thickness of a MaMbOz film may be reduced to half (A+B) while maintaining the same Ma and Mb contents as illustrated in FIG. 4 either by halving the thickness of each of the MaOx and MbOy films (A/2 and B/2) without changing the number of cycles shown in FIG. 4 or by halving the number of cycles (one cycle) without changing the thickness of each of the MaOx and MbOy films as illustrated in FIG. 6. Furthermore, a method of cleaning a surface of a solid without inflicting any damage thereon by forming a cluster, which is a group of blocky atoms or molecules of a material that is gaseous at a normal temperature, generating ions by applying electrons thereto, accelerating the ions, and irradiating the accelerated ions onto the surface of the solid, that is, implanting the ions into the shallow crust of the solid (refer to Reference 1).

[Reference 1] Japanese Patent Laid-Open Publication No. Hei 4-354865

### SUMMARY OF THE INVENTION

To solve the above and/or other problems, the present invention provides a method of processing a substrate, the method suitable for introducing an impurity into a thin film even when a thickness of the thin film is very small and/or a content of the impurity is very low.

According to an aspect of the present invention, there is provided a method of processing a substrate to form a thin film into which an impurity is introduced, the method comprising forming a thin film on the substrate; and introducing the impurity into the thin film by irradiating a gas cluster ion beam, which is generated by ionizing and accelerating a gas cluster of the impurity, onto the thin film.

A thickness of the thin film formed on the substrate may be no greater than 10 nm.

A content of the impurity in the thin film may be no greater than 10%.

The thin film formed on the substrate may comprise an insulating film containing Zr or Hf, and the impurity introduced into the thin film comprises Si, Ge, or Y.

The thin film may be thermally annealed after the impurity is introduced thereto.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view illustrating a method of processing a substrate, according to an exemplary embodiment of the present invention;

FIG. 2 is a sectional view illustrating a method of processing a substrate, according to a modification of an exemplary embodiment of the present invention;

FIG. 3 is a schematic diagram of a gas cluster ion beam irradiating device used in the exemplary embodiments described above;

FIG. 4 is a diagram illustrating a conventional method of processing a substrate;

FIG. 5 is a diagram illustrating another conventional method of processing a substrate; and

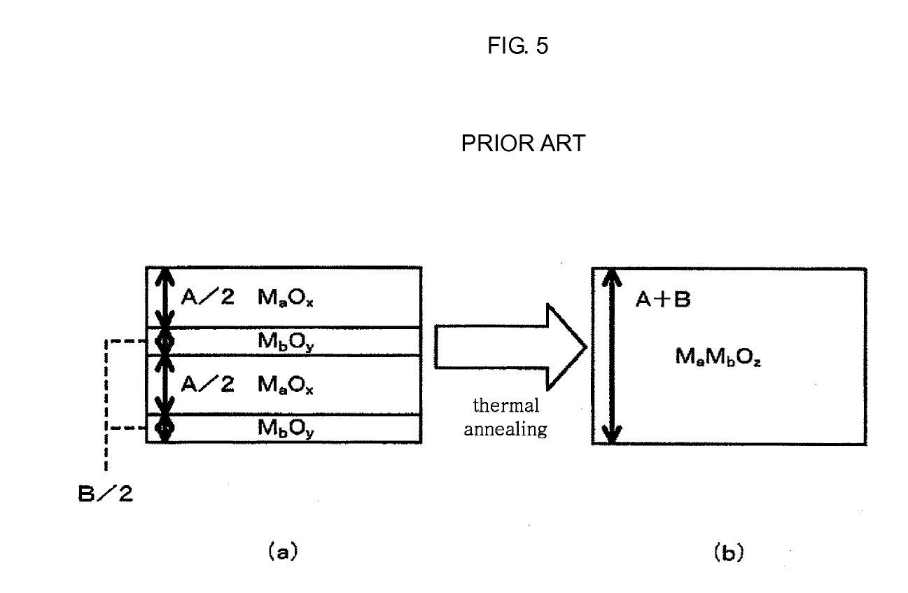

FIG. 6 is a diagram illustrating another conventional method of processing a substrate.

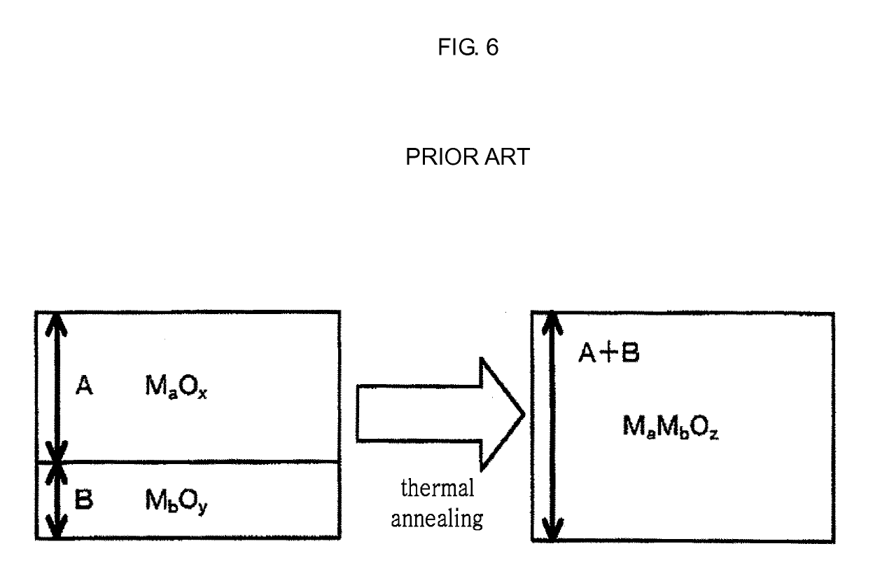

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

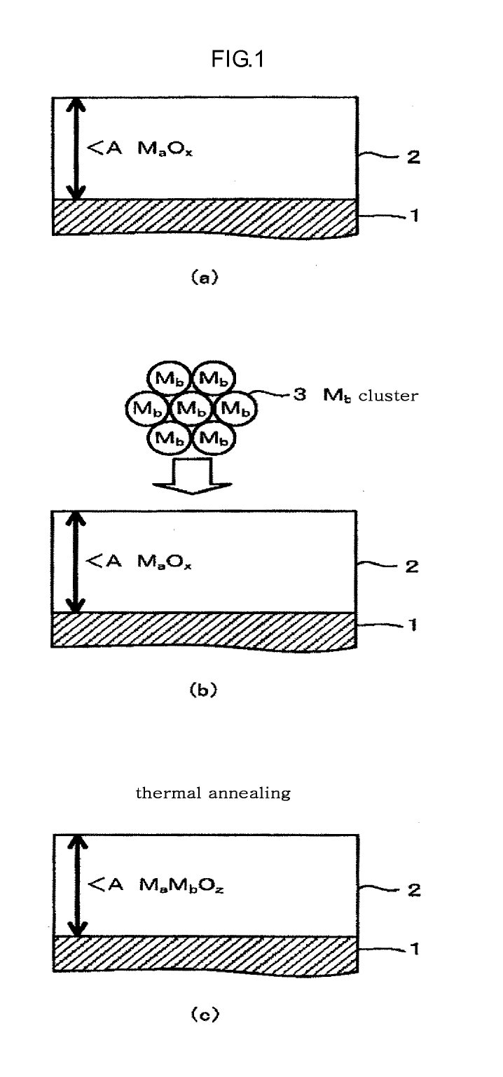

FIG. 1 is a sectional view illustrating a method of processing a substrate 1, according to an exemplary embodiment of the present invention, and show the main portion of the substrate 1 schematically.

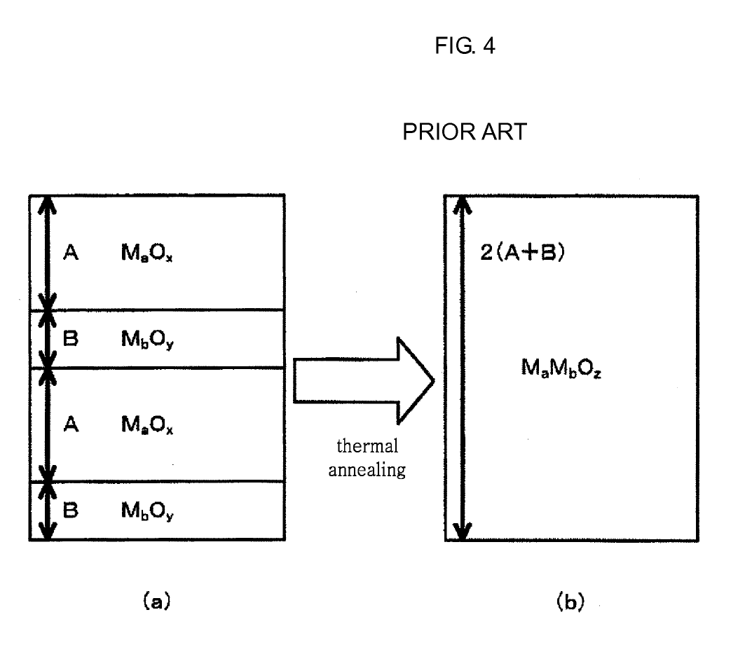

According to the present embodiment, as shown in (a) of FIG. 1, a thin film 2 formed of a predetermined material, e.g. an extremely thin film formed of a metal oxide MaOx, is formed on the substrate 1. The thickness of the thin film 2 may be less than the thickness A of a MaOx thin film illustrated in FIG. 4. For example, the thickness of the thin film 2 may be less than or equal to 10 nm.

Next, as shown in (b) of FIG. 1, a gas cluster ion beam 3, which is generated by ionizing gas clusters formed of an impurity and accelerating the clusters, is irradiated onto the thin film 2, wherein the atom density of the impurity may be, for example, from about 10²⁰ atoms/cm³ to about 10²¹ atoms/cm³, and the impurity may be a metal Mb. The amount of irradiation of the gas cluster ion beam 3a is adjusted depending on the amount of the impurity introduced.

Finally, shown in (c) of FIG. 1, the thin film 2, to which the gas cluster ion beam 3 is irradiated, is thermally annealed. As a result, the Mb content is controlled to be relatively low and thus, a MaMbOz film having a thickness less than A may be formed.

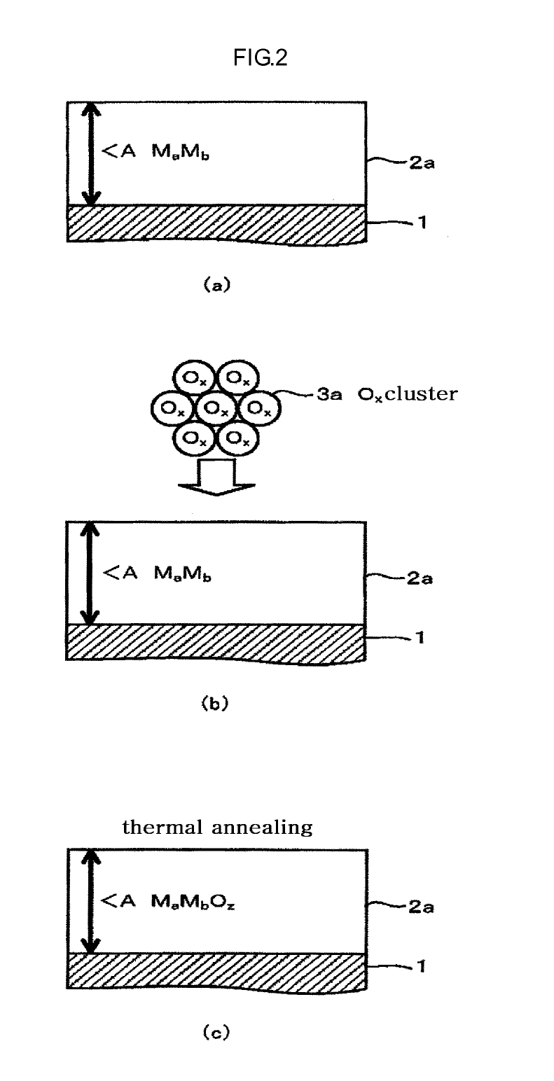

Alternatively, a method shown in FIG. 2 may be used. As shown in (a) of FIG. 2, a thin film 2a comprised of MaMb film is formed on the substrate 1. Next, as shown in (b) of FIG. 2, a gas cluster ion beam 3a, which includes oxygen Ox gas clusters with an atom density from about 10²⁰ atoms/cm³ to about 10²¹ atoms/cm³, is irradiated onto the thin film 2a. Finally, as shown in (c) of FIG. 2, a MaMbOz film is formed by thermally annealing the thin film 2a.

Thus, according to the embodiments of the present invention described above, a thin film with an impurity content less than or equal to several percents may be formed to have a thickness no greater than 10 nm, e.g. several nanometers. The method may be used to form, for example, an extremely thin ZrO₂ film or an extremely thin HfO₂ film with a thickness no greater than 10 nm and a low Si, Ge, or Y impurity content no greater than 10%. Thus, the content of an impurity may be easily adjusted.

Furthermore, according to the embodiments of the present invention described above, an impurity is clusterized before being introduced to an insulating film. Thus, an impurity may also be introduced at a low energy level, e.g. no greater than 10 eV per atom, which corresponds no greater than several thousand eV in the entire of clusters having several thousand atoms. Therefore, even if the thickness of the insulating film is very small, deterioration of characteristics, such as the impurity penetrating the insulating film and reacting with a material below the insulating film, may be inhibited.

Furthermore, according to the embodiments of the present invention described above, a MaMbOz film having a predetermined composition ratio may be easily formed by controlling the amount of a clusterized impurity introduced into a thin film. Furthermore, oxygen loss due to introduction of a clusterized impurity may be restored and/or an oxide film may be formed without irradiating an oxygen gas cluster ion beam by performing thermal annealing under an oxidizing atmosphere.

However, the extremely thin film with a low impurity content, e.g. an extremely thin ZrO2 film with a low Si content or an extremely thin HfO₂ film with a low Si content, may have improved permittivity by containing a low Si content as compared to a film containing no Si. In other words, since a crystal structure, such as a tetragonal system or a cubic system, may be easily formed by introducing Si, the unit volume of the thin film decreases, and thus permittivity may be improved.

Furthermore, such an extremely thin film having a high permittivity may be suitably used as an insulating film of a MIM capacitor of a DRAM of a semiconductor device or as a gate insulating film of a MOSFET.

In this regard, any materials may be used for forming a film on a substrate and as an impurity to be clusterized and introduced into the film.

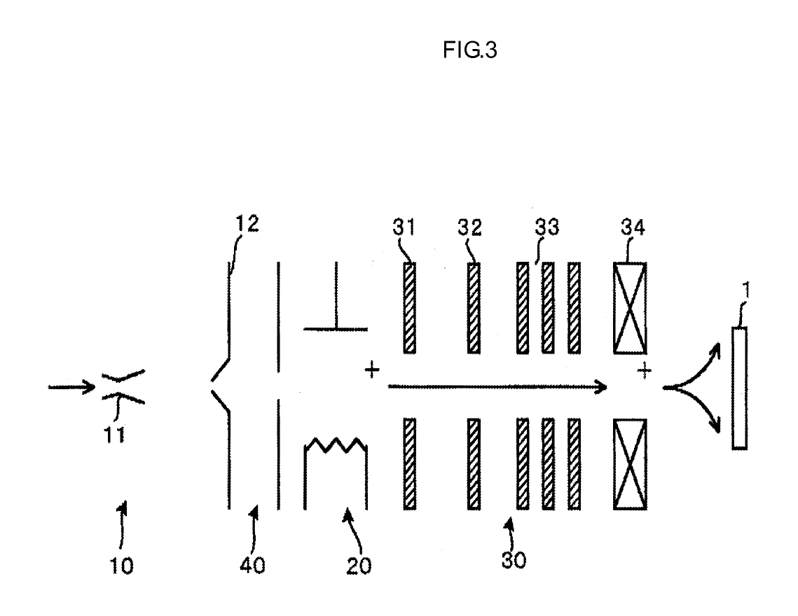

FIG. 3 is a schematic diagram of a gas cluster ion beam irradiating device used in the embodiments described above. Referring to FIG. 3, the gas cluster ion beam irradiating device includes a cluster generating unit 10, which clusterizes impurity gas under high pressure, an ionizing unit 20, which ionizes and charges the clusters, an acceleration-irradiating unit 30, which accelerates the charged clusters and introduces the accelerated clusters into a substrate, and a mechanism for holding a substrate 1. Furthermore, a differential exhaust unit 40 is provided between the cluster generating unit 10 and the ionizing unit 20.

In the cluster generating unit 10, gas clusters are generated by exhausting material gas at high pressure from a nozzle 11 into vacuum. A skimmer 12 is a cone-type orifice having sharp edges. Gas clusters are guided to the differential exhaust unit 40 via the skimmer 12, and then are introduced into the ionizing unit 20.

In the ionizing unit 20, gas clusters, which are electrically neutral, are ionized by colliding with thermoelectrons accelerated from a filament toward an anode. If the ionizing unit 20 is in a low-vacuum state, the atmospheric gas is ionized, and thus monomer ions are mixed in a gas cluster ion beam. Furthermore, gas cluster ions collide with the atmospheric gas, so that clusters collapse. Therefore, it is necessary to provide the differential exhaust unit 40 between the cluster generating unit 10 and the ionizing unit 20 to maintain a vacuum in the ionizing unit 20 as high as 6.65×10⁻³ Pa (up to about 5×10⁻⁵ Torr).

Then, gas cluster ions are accelerated via an extraction electrode 31 and an acceleration electrode 32. However, since the diameter of the gas cluster ion beam is increased through this process, the gas cluster ion beam is focused by a focusing lens 33. Then, monomers are removed by using a magnet 34, and the gas cluster ion beam is irradiated onto the substrate 1.

Although cases in which an impurity is introduced into metal oxides have been described above, the present invention is not limited thereto. That is, the method of processing a substrate according to the present invention may be widely applied as a general method of introducing an impurity into a thin film. Furthermore, the structure of a gas cluster ion beam irradiating device is not limited to the structure illustrated in FIG. 3, and any device having any structure may be used as long as the device is capable of irradiating a gas cluster ion beam.

What is claimed is:

1. A method of processing a substrate to form a thin film into which an impurity is introduced, the method comprising:
forming a thin film on the substrate; and
introducing the impurity into the thin film by irradiating a gas cluster ion beam, which is generated by ionizing and accelerating a gas cluster of the impurity, onto the thin film.

2. The method of claim 1, wherein a thickness of the thin film formed on the substrate is no greater than 10 nm.

3. The method of claim 1, wherein a content of the impurity in the thin film is no greater than 10%.

4. The method of claim 1, wherein the thin film formed on the substrate comprises an insulating film containing Zr or Hf, and the impurity introduced into the thin film comprises Si, Ge, or Y.

5. The method of claim 1, wherein the thin film is thermally annealed after the impurity is introduced thereto.
